(19) United States
(12) Patent Application Publication
(10) Pub. No.: US 2026/0261025 A1
(43) Pub. Date: Sep. 3, 2026

(54) A RADIO FREQUENCY SLIP RING AND A METHOD TO ASSEMBLE THE SAME

(71) Applicant: AMPHENOL INTERCONNECT INDIA PVT. LTD, Pune (IN)

(72) Inventors: Apurva A. Choudhari, PUNE (IN); Jalilul Rehman Khan, PUNE (IN)

(21) Appl. No.: 19/489,913

(22) PCT Filed: Jan. 11, 2024
(86) PCT No.: PCT/IB2024/050268

§ 371 Date: Dec. 4, 2025

(30) Foreign Application Priority Data
Jun. 19, 2023 (IN) 202321041603

(51) Int. Cl. H01P 1/06

(52) U.S. Cl. CPC H01P 1/066

(57) ABSTRACT

A radio frequency (RF) slip ring 100 is disclosed. The RF slip ring includes an outer assembly 102 that includes a flange 106 to accommodate the RF contact 108 to transfer maximum RF signal power with minimal loss. The RF contact is a structure combining a spring and RF power divider 114 and disposed on a plate including a central bore 110. The output section includes a shielding ring 116 circumferentially paired to the plate along the outer edge. The RF slip ring includes an input section assembled with the output section and includes a circular projection 120 arranged circumferentially within a housing 118. The housing includes a ring 122 disposed to pair with the RF contact. The RF slipring enables 35% to 40% transmission line contact for energy transfer, low contact force for high service life. The RF slip ring is stackable for forming a plurality of channels 124.

### EARLIEST PRIORITY DATE

This Application claims priority from a provisional patent application filed in India having Patent Application No. 202321041603, filed on Jun. 19, 2023, and titled “A RADIO FREQUENCY SLIP RING AND A METHOD THEREOF” and PCT application filed having Patent Application No. PCT/IB 2024/050268, filed on Jan. 11, 2024, and titled “A RADIO FREQUENCY SLIP RING AND A METHOD TO ASSEMBLE THE SAME”.

### FIELD OF INVENTION

Embodiments of a present disclosure relate to slip rings and more particularly to a radio frequency slip ring and a method to assemble the same.

### BACKGROUND

A slip ring is an essential component in many rotating systems such as rotary joints. The slip ring is an electromechanical device that allows the transmission of power and electrical signals from a stationary to a rotating structure and are used to simplify the operation of a system or improve its mechanical performance. Slip rings are used in systems that require relative rotation to transmit signals and currents. The slip rings are divided according to their working principles such as smooth rings, electric slip rings, radio frequency (RF) slip rings, and the like.

Currently, the existing RF Rotary Joint or RF slip rings is a contact type ring design with a contact point at one single spot. This design has its own limitations to operating frequencies and need to be of a customized size for specific frequency and applications. Moreover, for a product with RF rotary joint or RF slip ring, the product's contact surfaces need to be cleaned at regular intervals and at times, lubricated, to get consistent RF performance throughout the product life. The currently available RF slip rings have less effective contacting surface and high contact force between a ring and a brush. Further, due to wear, a periodic cleaning of the components or parts of the RF slip ring is a must.

Hence, there is a need for a radio frequency slip ring and a method to assemble the same which addresses the aforementioned issues.

### OBJECTIVE OF THE INVENTION

An objective of the present invention is to provide a customized sized radio frequency (RF) slip ring for specific operating frequency and applications.

Another objective of the preset invention is to provide a high product operating life and zero to low maintenance.

Yet, an objective of the present invention is to provide ring and brush contacts with extremely low contact force which increases the effectiveness of joints.

Further, an objective of the present invention is to transfer maximum amount of RF signal power with minimal reflection & insertion losses in the path.

Furthermore, an objective of the present invention is to eliminate periodic cleaning of the RF slip ring due to low wear between the contact surfaces.

Furthermore, an objective of the present invention is to match the impedance between the RF contact to the rotating ring for continued low loss RF signal transmission.

### BRIEF DESCRIPTION

In accordance with one embodiment of the disclosure, a radio frequency slip ring is provided. The radio frequency slip ring includes an outer ring assembly and an inner ring assembly. The outer assembly is configured to assemble with an inner assembly. The outer assembly includes a flange adapted to accommodate a radio frequency contact for transferring a radio frequency signal power to a stationary plane. The radio frequency contact is disposed atop a plate, adapted to fit into the outer assembly. The radio frequency contact includes a central bore formed with a U-shaped structure. The central bore includes a combination of a spring and a radio frequency power divider. The radio frequency power divider effectively transmits power over the contact area. The radio frequency contact includes a shielding ring adapted to pair circumferentially with the plate along the outer edge of the outer assembly. The inner assembly includes a housing to accommodate a plurality of input components. The housing includes a circular projection arranged circumferentially within the housing. The housing also includes a ring disposed within the housing and adapted to pair with the radio frequency contact structure when assembled, the inner assembly and the outer assembly are adapted to stack to form a plurality of channels, wherein each stacked channel comprises a shielding circuitry and a bearing for smooth rotation of a rotary joint formed by the inner assembly and the outer assembly.

In accordance with another embodiment a method for assembling the radio frequency slip rings is provided. The method includes providing, a flange on an outer assembly. The flange transfers a radio frequency signal power to a stationary place. The method also includes disposing, a radio frequency contact atop a plate and adapted to fit into the outer assembly. The method also includes providing, a central bore with U-shaped structure with a combination of a spring and a radio frequency power divider. Note the U-shaped structure contact can/will vary depending on the power divider design-consider U, Double U, M/W etc. but still maintains the spring characteristics. Further, the method includes circumferentially paring, by a shielding ring with the plate along the outer edge of the outer assembly. Furthermore, the method includes arranging, a circular projection circumferentially within a housing of an inner assembly disposing, a ring within the housing and adapted to pair with the radio frequency contact structure when assembled. Furthermore, the method includes forming, a plurality of channels by stacking the inner assembly and the outer assembly. Furthermore, the method includes providing, a shielding circuitry and a bearing for each stacked channel for smooth rotation of a rotary joint formed by the inner assembly and the outer assembly. The channel can be single through upwards of 10, depending on the centre hollow diameter of the rings and isolation requirements. Note that larger the ring size, the RF performance degrades, and the bandwidth reduces. The compromise on the same can be done based on each application and frequency band of operation.

To further clarify the advantages and features of the present disclosure, a more particular description of the disclosure will follow by reference to specific embodiments thereof, which are illustrated in the appended figures. It is to be appreciated that these figures depict only typical embodiments of the disclosure and are therefore not to be considered limiting in scope. The disclosure will be described and explained with additional specificity and detail with the appended figures.

### BRIEF DESCRIPTION OF THE DRAWINGS

The disclosure will be described and explained with additional specificity and detail with the accompanying figures in which:

FIG. 1a is a schematic representation of an outer assembly of the radio frequency slip ring in accordance with an embodiment of the present disclosure;

FIG. 1b is a top view of the outer assembly of the radio frequency slip ring of FIG. 1a in accordance with an embodiment of the present disclosure;

FIG. 1c is a schematic representation of an inner assembly of the radio frequency slip ring in accordance with an embodiment of the present disclosure;

FIG. 2a is a schematic representation of the outer assembly of FIG. 1a in accordance with an embodiment of the present disclosure;

FIG. 2b is a schematic representation of the stacked radio slip rings of FIG. 1a and FIG. 1b in accordance with an embodiment of the present disclosure;

FIG. 2c is a schematic representation of isometric view of the inner assembly of the radio frequency slip ring in accordance with an embodiment of the present disclosure;

FIG. 3 is a schematic representation of side view of single channel unit that can be stacked on top of each other of FIG. 1a and FIG. 1b in accordance with an embodiment of the present disclosure; and

FIG. 4 is a flow chart representing steps involved in a method of assembling the radio frequency slip ring in accordance with an embodiment of the present disclosure.

Further, those skilled in the art will appreciate that elements in the figures are illustrated for simplicity and may not have necessarily been drawn to scale Furthermore, in terms of the construction of the device, one or more components of the device may have been represented in the figures by conventional symbols, and the figures may show only those specific details that are pertinent to understanding the embodiments of the present disclosure so as not to obscure the figures with details that will be readily apparent to those skilled in the art having the benefit of the description herein.

### DETAILED DESCRIPTION

For the purpose of promoting an understanding of the principles of the disclosure, reference will now be made to the embodiment illustrated in the figures and specific language will be used to describe them. It will nevertheless be understood that no limitation of the scope of the disclosure is thereby intended. Such alterations and further modifications in the illustrated system, and such further applications of the principles of the disclosure as would normally occur to those skilled in the art are to be construed as being within the scope of the present disclosure.

The terms “comprises”, “comprising”, or any other variations thereof, are intended to cover a non-exclusive inclusion, such that a process or method that comprises a list of steps does not include only those steps but may include other steps not expressly listed or inherent to such a process or method. Similarly, one or more devices or sub-systems or elements or structures or components preceded by “comprises . . . a” does not, without more constraints, preclude the existence of other devices, sub-systems, elements, structures, components, additional devices, additional sub-systems, additional elements, additional structures, or additional components. Appearances of the phrase “in an embodiment”, “in another embodiment” and similar language throughout this specification may, but not necessarily do, all refer to the same embodiment.

Unless otherwise defined, all technical and scientific terms used herein have the same meaning as commonly understood by those skilled in the art to which this disclosure belongs. The system, methods, and examples provided herein are only illustrative and not intended to be limiting.

In the following specification and the claims, reference will be made to a number of terms, which shall be defined to have the following meanings. The singular forms “a”, “an”, and “the” include plural references unless the context clearly dictates otherwise.

Embodiments of the present disclosure relate to a radio frequency slip ring. The radio frequency slip ring includes an outer ring assembly and an inner ring assembly. The outer assembly is configured to assemble with an inner assembly. The outer assembly includes a flange adapted to accommodate a radio frequency contact for transferring a radio frequency signal power to a stationary plane. the radio frequency contact is disposed atop a plate, adapted to fit into the outer assembly. The radio frequency contact includes a central bore formed with a U-shaped structure. The central bore includes a combination of a spring and a radio frequency power divider. The radio frequency power divider reduces pressure on the radio frequency contact. The radio frequency contact includes a shielding ring adapted to pair circumferentially with the plate along the outer edge of the outer assembly. The inner assembly includes a housing to accommodate a plurality of input components. The housing includes a circular projection arranged circumferentially within the housing. The housing also includes a ring disposed within the housing and adapted to pair with the radio frequency contact structure when assembled. the inner assembly and the outer assembly are adapted to stack to form a plurality of channels, wherein each stacked channel comprises a shielding circuitry and a bearing for smooth rotation of a rotary joint formed by the inner assembly and the outer assembly.

Note the U-shaped structure contact can vary depending on the power divider design-for example U-shaped, Double U-shaped, M/W-shaped and the like, but still maintains the spring characteristics.

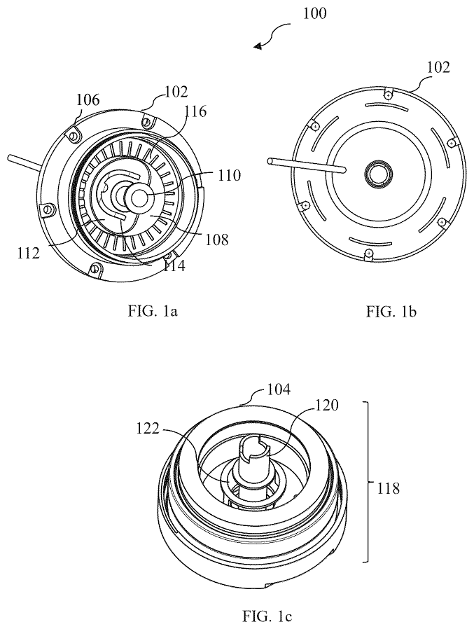

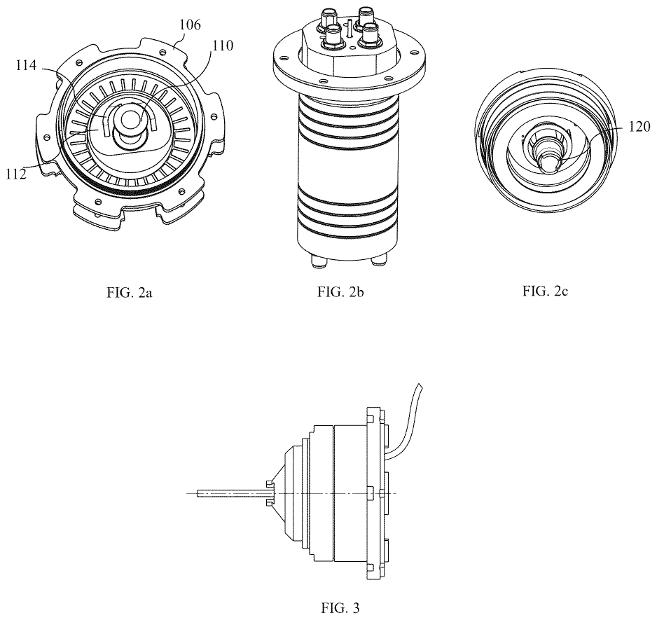

FIG. 1a is a schematic representation of an outer assembly of the radio frequency slip ring in accordance with an embodiment of the present disclosure. The radio frequency slip ring includes an outer assembly 102 configured to assemble with an inner assembly (104, FIG. 1c). The outer assembly 102 includes a flange 106 adapted to accommodate a radio frequency contact 108 for transferring a radio frequency signal power to a stationary plane. The radio frequency contact 108 is disposed atop a plate (not shown in FIG. 1a), adapted to fit into the outer assembly 102. The radio frequency contact 108 includes a central bore 110 formed with a U-shaped structure 112. In one embodiment, the central bote 110 is formed with Y-shaped, Half circle-shaped, and the like. The central bore 110 includes a combination of a spring (not shown in FIG. 1a) and a radio frequency power divider 114. The radio frequency power divider 114 reduces pressure on the radio frequency contact 108.

The radio frequency contact 108 also includes a shielding ring 116 adapted to pair circumferentially with the plate along the outer edge of the outer assembly 102. In one embodiment, the shielding ring 116 may be used in microwave cavities, tuning, shielding, and grounding applications.

FIG. 1b is a top view of the outer assembly 102 of the radio frequency slip ring of FIG. 1a in accordance with an embodiment of the present disclosure. FIG. 1c is a schematic representation of an inner assembly of the radio frequency slip ring in accordance with an embodiment of the present disclosure. The inner assembly 104 includes a housing 118 to accommodate a plurality of input components. The housing 118 includes a circular structure 120 and a ring 122. The circular projection 120 is arranged circumferentially within the housing 118. The ring 122 is disposed within the housing 118 and adapted to pair with the radio frequency contact (108) when assembled.

The inner assembly 104 and the outer assembly 102 are adapted to stack to form a plurality of channels 124. Each stacked channel includes a shielding circuitry and a bearing for smooth rotation of a rotary joint formed by the inner assembly 104 and the outer assembly 102. In one embodiment, each stacked channel may have an individual shielding circuitry to increase RF isolation, its own bearing for smooth rotation and low torque.

FIG. 2a is a schematic representation of the outer assembly 102 of FIG. 1a in accordance with an embodiment of the present disclosure. In one embodiment, the plate is fabricated with an outer coating of a hard gold or Quad metal WearProTech plating, wherein the coating is adapted to enhance the wear resistance. In one embodiment, the power divider 114 is adapted to split a radio frequency path and transfer absolute amount of radio frequency signal power with reduced reflections and losses in the radio frequency path. In one embodiment, the ring 122 and the radio frequency contact 108 is fabricated with a base material 128 of copper alloy.

FIG. 2b is a schematic representation of the stacked radio slip rings of FIG. 1a and FIG. 1b in accordance with an embodiment of the present disclosure. In one embodiment, the housing 118 includes a vertical projection 126 adapted to mesh with the central bore 110 of the plate.

FIG. 2c is a schematic representation of isometric view of the inner assembly 104 of the radio frequency slip ring in accordance with an embodiment of the present disclosure. The inner assembly 104 and the outer assembly 102 are adapted to stack to form a plurality of channels 124. Each stacked channel includes a shielding circuitry and a bearing for smooth rotation of a rotary joint formed by the inner assembly 104 and the outer assembly 102. In one embodiment, each stacked channel may have an individual shielding circuitry to increase RF isolation, its own bearing for smooth rotation and low torque.

FIG. 3 is a schematic representation of side view of single channel unit that can be stacked on top of each other of FIG. 1a and FIG. 1b in accordance with an embodiment of the present disclosure. In one embodiment, the radio frequency (RF) slip ring as is incorporated with unique RF contacts, optimized to transfer maximum RF signal power with minimal losses in the transmission path-while one plan is stationary, and the other is rotating. The RF slip ring provides a small form factor and can be stacked to multi-channel RF Sliprings. Each stacked channel (RF path) has an individual shielding circuitry to increase RF isolation. Also, each stacked channel has its own bearing for smooth rotation and low torque. In one embodiment, the RF contact pressure is made very low due to the contact surface coverage for effecting signal transmission without compromising signal integrity. In one embodiment, the contact surface coverage may be over 35%. The base material 128 of the ring and contacts are of copper alloy. In one embodiment, the plating finish may be made of Quad metal WearProTech plating which further enhances the wear resistance to a factor of 9 over Gold. In one embodiment, the Quad metal WearProTech plating is a plating process featuring quad plating system for enhanced appearance, corrosion resistance & wear resistance.

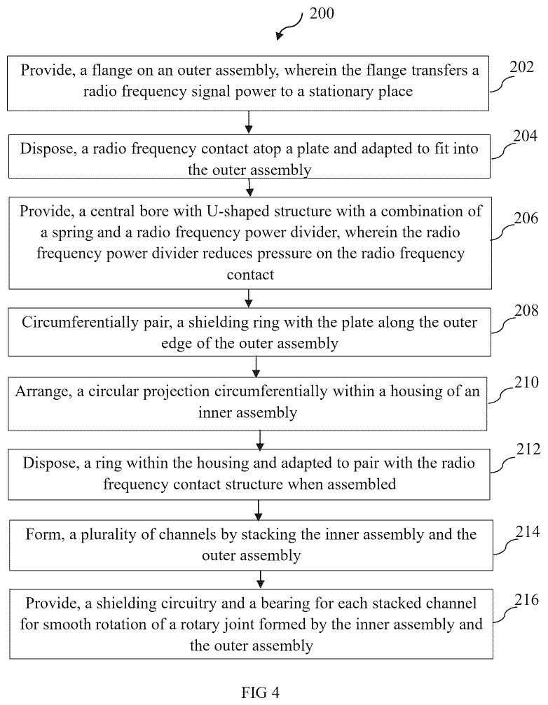

FIG. 4 is a flow chart representing steps involved in a method (200) of assembling the radio frequency slip ring in accordance with an embodiment of the present disclosure. The method 200 includes providing a flange on an outer assembly, wherein the flange transfers a radio frequency signal power to a stationary place in step 202.

The method 200 also includes disposing, a radio frequency contact atop a plate and adapted to fit into the outer assembly in step 204. The method 200 also includes fabricating, the plate with an outer coating of a hard gold or Quad metal WearProTech plating, wherein the coating is adapted to enhance the wear resistance. In one embodiment, the Quad metal WearProTech plating is a plating process featuring quad plating system for enhanced appearance, corrosion resistance & wear resistance.

Further, the method 200 includes providing, a central bore with U-shaped structure with a combination of a spring and a radio frequency power divider, wherein the radio frequency power divider reduces pressure on the radio frequency contact in step 206. In one embodiment, the central bore may be with Y-shaped, Half circle-shaped, and the like. The method also includes the radio frequency power divider is adapted to split a radio frequency path and transfer absolute amount of radio frequency signal power with reduced reflections and losses in the radio frequency path.

Furthermore, the method 200 includes circumferentially paring, by a shielding ring with the plate along the outer edge of the outer assembly in step 208.

Furthermore, the method 200 includes arranging, a circular projection circumferentially within a housing of an inner assembly in step 210. The method also includes providing, a vertical projection adapted to mesh with the central bore of the plate.

Furthermore, the method 200 includes disposing, a ring within the housing and adapted to pair with the radio frequency contact structure when assembled in step 212. In one embodiment, the ring and the radio frequency contact is fabricated with a base material including a Copper alloy material.

Furthermore, the method 200 includes forming, a plurality of channels by stacking the inner assembly and the outer assembly in step 214.

Furthermore, the method 200 includes providing, a shielding circuitry and a bearing for each stacked channel for smooth rotation of a rotary joint formed by the inner assembly and the outer assembly in step 216.

Various embodiments of the present disclosure enable a customized sized radio frequency (RF) slip ring for specific operating frequency and applications. The RF contact surfaces disclosed in the present disclosure can be cleaned at regular intervals and at times, lubricated, to get consistent RF performance throughout the product life. The RF slip ring disclosed in the present disclosure when installed in a product provides a high product operating life and low to no maintenance. The RF slip ring provides the ring and brush contacts having an effective of 35% to 40% contacting surface and extremely low contact force between the ring and brush.

Further, the RF slip ring disclosed in the present disclosure incorporates the power divider to split the RF path and transfer maximum amount of RF signal power with minimal reflections and losses in the path. Due to low wear, no periodic cleaning of the RF slip ring is required. The RF slip ring disclosed in the present disclosure matches the impedance between the RF contact to the rotating ring for continued low loss RF signal transmission.

While specific language has been used to describe the disclosure, any limitations arising on account of the same are not intended. As would be apparent to a person skilled in the art, various working modifications may be made to the method in order to implement the inventive concept as taught herein.

The figures and the foregoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, order of processes described herein may be changed and are not limited to the manner described herein. Moreover, the actions of any flow diagram need not be implemented in the order shown; nor do all of the acts need to be necessarily performed. Also, those acts that are not dependent on other acts may be performed in parallel with the other acts. The scope of embodiments is by no means limited by these specific examples.

We claim:

1. A radio frequency slip ring comprising:
an outer assembly configured to assemble with an inner assembly, wherein the outer assembly comprises:
a flange adapted to accommodate a radio frequency contact for transferring a radio frequency signal power to a stationary plane;
characterized in that:
the radio frequency contact is disposed atop a plate, adapted to fit into the outer assembly wherein the radio frequency contact comprises:
a central bore formed with a U-shaped structure comprising:
a combination of a spring and a radio frequency power divider, wherein the radio frequency power divider reduces pressure on the radio frequency contact;
a shielding ring adapted to pair circumferentially with the plate along the outer edge of the outer assembly;
the inner assembly comprises a housing to accommodate a plurality of input components, wherein the housing comprises:
a circular projection arranged circumferentially within the housing; and
a ring disposed within the housing and adapted to pair with the radio frequency contact when assembled; and
thereby forming a plurality of channels by stacking the inner assembly and the outer assembly, wherein each stacked channel comprises a shielding circuitry and a bearing for smooth rotation of a rotary joint formed by the inner assembly and the outer assembly.

2. The radio frequency slip ring as claimed in claim 1, wherein the plate is fabricated with an outer coating of at least one of a hard gold or Quad metal WearProTech plating, wherein the coating is adapted to enhance the wear resistance.

3. The radio frequency slip ring as claimed in claim 1, wherein the radio frequency power divider is adapted to split a radio frequency path and transfer absolute amount of radio frequency signal power with reduced reflections and losses in the radio frequency path.

4. The radio frequency slip ring as claimed in claim 1, wherein the housing comprises a vertical projection adapted to mesh with the central bore of the plate.

5. The radio frequency slip ring as claimed in claim 1, wherein the ring and the radio frequency contact is fabricated with a base material comprising a Copper alloy material.

6. A method for assembling the radio frequency slip ring comprising:
providing, a flange on an outer assembly, wherein the flange transfers a radio frequency signal power to a stationary place;
characterized in that:
disposing, a radio frequency contact atop a plate and adapted to fit into the outer assembly;
providing, a central bore with U-shaped structure with a combination of a spring and a radio frequency power divider, wherein the radio frequency power divider reduces pressure on the radio frequency contact;
circumferentially paring, by a shielding ring with the plate along the outer edge of the outer assembly;
arranging, a circular projection circumferentially within a housing of an inner assembly;
disposing, a ring within the housing and adapted to pair with the radio frequency contact structure when assembled;
forming, a plurality of channels by stacking the inner assembly and the outer assembly; and
providing, a shielding circuitry and a bearing for each stacked channel for smooth rotation of a rotary joint formed by the inner assembly and the outer assembly.
